(19) United States
(12) Patent Application Publication
(10) Pub. No.: US 2021/0013274 A1
(43) Pub. Date: Jan. 14, 2021

(54) LIGHT EMITTING PANEL AND DISPLAY APPARATUS

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ruiting HE, Wuhun, Hubei (CN)

(21) Appl. No.: 16/630,444

(22) PCT Filed: Oct. 21, 2019
(86) PCT No.: PCT/CN2019/112208

§ 371 Date: Jan. 12, 2020

(30) Foreign Application Priority Data
Jul. 10, 2019 (CN) 201910617977.0

(51) Int. Cl. H01L 27/32

(52) U.S. Cl. CPC H01L 27/3218; H01L 27/326

(57) ABSTRACT

A light emitting substrate includes a base and pixel unit sets arranged on the base, wherein the pixel unit sets include a first sub-pixel, a second sub-pixel, and a third sub-pixel having colors different from each other, wherein adjacent sub-pixels have space therebetween, the pixel unit sets arranged in a same row include a first pixel unit set and a second pixel unit set adjacent to each other, the second sub-pixel of the first pixel unit set and the first sub-pixel of the second pixel unit set have a same color, the second sub-pixel of a third pixel unit set located in an adjacent row and on a side of the first sub-pixel and the third sub-pixel of the first pixel unit set have a same color, and the first sub-pixel of a fourth pixel unit set and the third sub-pixel of the first pixel unit set have a same color.

### FIELD OF INVENTION

The present application relates to the technical field of display, and especially to a light emitting substrate and a display apparatus.

### BACKGROUND OF INVENTION

In recent years, organic light emitting diodes (OLEDs) having many advantageous properties such as self-luminous, low power consumption, wide viewing angles, richness in colors, quick response times, and ability to manufacture flexible screens have attracted great attention in the research community and industry, and are considered as a promising display technology of the next generation.

In the related technologies, fine metal masks (FMMs) are generally adopted to perform evaporation when manufacturing OLED pixels, and in order to achieve high resolution, openings on FMMs are required to be made small to form pixels with smaller dimensions that can be densely arranged on a base. However, this kind of manufacturing method requires control of some factors such as alignment precision of FMMs, etc., and because pixels with smaller dimensions are arranged excessively dense, color mixture easily occurs.

Therefore, drawbacks exist in the conventional technology and are in urgent need of improvement.

### SUMMARY OF INVENTION

An embodiment of the present application provides a light emitting substrate and a display apparatus, which can increase resolution, prevent color mixture, and decrease manufacturing difficulties at the same time.

In a first aspect, an embodiment of the present application provides a light emitting substrate that includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row includes a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set.

A light emitting substrate according to the present application, wherein the first sub-pixel, the second sub-pixel, and the third sub-pixel are arranged surrounding a central axis, and the central axis is perpendicular to the base.

A light emitting substrate according to the present application, wherein the first sub-pixel, the second sub-pixel, and the third sub-pixel of the pixel unit sets have a same shape.

A light emitting substrate according to the present application, wherein the first sub-pixel includes a first side and a second side adjacent to the first side, the first side and the second side are sides closer to the central axis, the second sub-pixel includes a third side and a fourth side adjacent to the third side, the third side and the fourth side are sides closer to the central axis, the third sub-pixel includes a fifth side and a sixth side adjacent to the fifth side, and the fifth side and the sixth side are sides closer to the central axis.

A light emitting substrate according to the present application, wherein a sum of a first angle, a second angle, and a third angle is 360 degrees, the first angle is an angle formed by the first side and the second side, the second angle is an angle formed by the third side and the fourth side, and the third angle is an angle formed by the fifth side and the sixth side.

A light emitting substrate according to the present application, wherein the third side is disposed facing the first side, the fifth side is disposed facing the second side, and the fourth side is disposed facing the sixth side.

A light emitting substrate according to the present application, wherein each shape of the first sub-pixel, the second sub-pixel, and the third sub-pixel is a rhombus, a shape of the pixel unit set formed by the first sub-pixel, the second sub-pixel, and the third sub-pixel is a regular hexagon, and a center point of the regular hexagon is located at the central axis.

A light emitting substrate according to the present application, wherein the pixel unit sets in adjacent rows are shifted with a preset width, and the preset width is equal to half of a width of the pixel unit sets in a horizontal direction.

A light emitting substrate according to the present application, wherein each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

In a second aspect, an embodiment of the present application further provides a display apparatus that includes a light emitting substrate and a housing, wherein the light emitting substrate is disposed on the housing, and the light emitting substrate includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row includes a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set.

A display apparatus according to the present application, wherein the first sub-pixel, the second sub-pixel, and the third sub-pixel are arranged surrounding a central axis, and the central axis is perpendicular to the base.

A display apparatus according to the present application, wherein the first sub-pixel, the second sub-pixel, and the third sub-pixel of the pixel unit sets have a same shape.

A display apparatus according to the present application, wherein the first sub-pixel includes a first side and a second side adjacent to the first side, the first side and the second side are sides closer to the central axis, the second sub-pixel includes a third side and a fourth side adjacent to the third side, the third side and the fourth side are sides closer to the central axis, the third sub-pixel includes a fifth side and a sixth side adjacent to the fifth side, and the fifth side and the sixth side are sides closer to the central axis.

A display apparatus according to the present application, wherein a sum of a first angle, a second angle, and a third angle is 360 degrees, the first angle is an angle formed by the first side and the second side, the second angle is an angle formed by the third side and the fourth side, and the third angle is an angle formed by the fifth side and the sixth side.

A display apparatus according to the present application, wherein the third side is disposed facing the first side, the fifth side is disposed facing the second side, and the fourth side is disposed facing the sixth side.

A display apparatus according to the present application, wherein each shape of the first sub-pixel, the second sub-pixel, and the third sub-pixel is a rhombus, a shape of the pixel unit set formed by the first sub-pixel, the second sub-pixel, and the third sub-pixel is a regular hexagon, and a center point of the regular hexagon is located at the central axis.

A display apparatus according to the present application, wherein the pixel unit sets in adjacent rows are shifted with a preset width, and the preset width is equal to half of a width of the pixel unit sets in a horizontal direction.

A display apparatus according to the present application, wherein each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

In a third aspect, an embodiment of the present application further provides light emitting substrate that includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row includes a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, the third pixel unit set and the fourth pixel unit set are located on two sides of the first pixel unit set, the first sub-pixel, the second sub-pixel, and the third sub-pixel are arranged surrounding a central axis, the central axis is perpendicular to the base, the pixel unit sets in adjacent rows are shifted with a preset width, and the preset width is equal to half of a width of the pixel unit sets in a horizontal direction.

A light emitting substrate according to the present application, wherein the first sub-pixel, the second sub-pixel, and the third sub-pixel of the pixel unit sets have a same shape, each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

An embodiment of the present application provides a light emitting substrate that includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the second sub-pixel of the first pixel unit set and the first sub-pixel of the second pixel unit set of the plurality of pixel unit sets arranged in a same row that are adjacent to each other have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set. By using a mask to yield space between each sub-pixel arranged on the base, color mixture can be prevented, and each pixel unit set having sub-pixels with different colors can increase resolution. Meanwhile, it is not necessary to reduce size of openings of the mask and manufacturing difficulty can be reduced.

### DESCRIPTION OF DRAWINGS

The accompanying figures to be used in the description of embodiments of the present application will be described in brief to more clearly illustrate the technical solutions of the embodiments. The accompanying figures described below are only part of the embodiments of the present application, from which those skilled in the art can derive further figures without making any inventive efforts.

FIG. 1 is a structural schematic diagram of a display apparatus according to an embodiment of the present application.

FIG. 2 is a first structural schematic diagram of a light emitting substrate according to an embodiment of the present application.

FIG. 3 is a second structural schematic diagram of a light emitting substrate according to an embodiment of the present application.

FIG. 4 is a third structural schematic diagram of a light emitting substrate according to an embodiment of the present application.

FIG. 5 is a fourth structural schematic diagram of a light emitting substrate according to an embodiment of the present application.

FIG. 6 is a structural schematic diagram of masks for manufacturing sub-pixels according to an embodiment of the present application.

### DETAILED DESCRIPTION OF PREFERRED EMBODIMENTS

The embodiments of the present application are described in detail hereinafter. Examples of the described embodiments are given in the accompanying drawings. It should be noted that the following embodiments are intended to illustrate and interpret the present application, and shall not be construed as causing limitations to the present application. Similarly, the following embodiments are part of the embodiments of the present application and are not the whole embodiments, and all other embodiments obtained by those skilled in the art without making any inventive efforts are within the scope protected by the present application.

In the conventional technology, fine metal masks (FMMs) are generally adopted to perform evaporation when manufacturing organic light emitting diode (OLED) pixels, and in order to achieve high resolution, openings on FMMs are required to be made small to form pixels with smaller dimensions that can be densely arranged on a base. However, this kind of manufacturing method requires control of some factors such as alignment precision of FMMs, shadows of masks, etc., and is more difficult to manufacture; furthermore, more densely arranged pixels easily lead to the problem of color mixture. Smaller space between adjacent openings on FMMs easily leads to deformation of FMMs, and this kind of FMMs are more difficult to use during processing.

An embodiment of the present application provides a display apparatus that includes a light emitting substrate and a housing, wherein the light emitting substrate is disposed on the housing, and the light emitting substrate includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row includes a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set.

Wherein, the first sub-pixel, the second sub-pixel, and the third sub-pixel are arranged surrounding a central axis, and the central axis is perpendicular to the base.

Wherein, the first sub-pixel, the second sub-pixel, and the third sub-pixel of the pixel unit sets have a same shape.

Wherein, the first sub-pixel includes a first side and a second side adjacent to the first side, the first side and the second side are sides closer to the central axis, the second sub-pixel includes a third side and a fourth side adjacent to the third side, the third side and the fourth side are sides closer to the central axis, the third sub-pixel includes a fifth side and a sixth side adjacent to the fifth side, and the fifth side and the sixth side are sides closer to the central axis.

Wherein, a sum of a first angle, a second angle, and a third angle is 360 degrees, the first angle is an angle formed by the first side and the second side, the second angle is an angle formed by the third side and the fourth side, and the third angle is an angle formed by the fifth side and the sixth side.

Wherein, the third side is disposed facing the first side, the fifth side is disposed facing the second side, and the fourth side is disposed facing the sixth side.

Wherein, each shape of the first sub-pixel, the second sub-pixel, and the third sub-pixel is a rhombus, a shape of the pixel unit set formed by the first sub-pixel, the second sub-pixel, and the third sub-pixel is a regular hexagon, and a center point of the regular hexagon is located at the central axis.

Wherein, the pixel unit sets in adjacent rows are shifted with a preset width, and the preset width is equal to half of a width of the pixel unit sets in a horizontal direction.

Wherein, each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

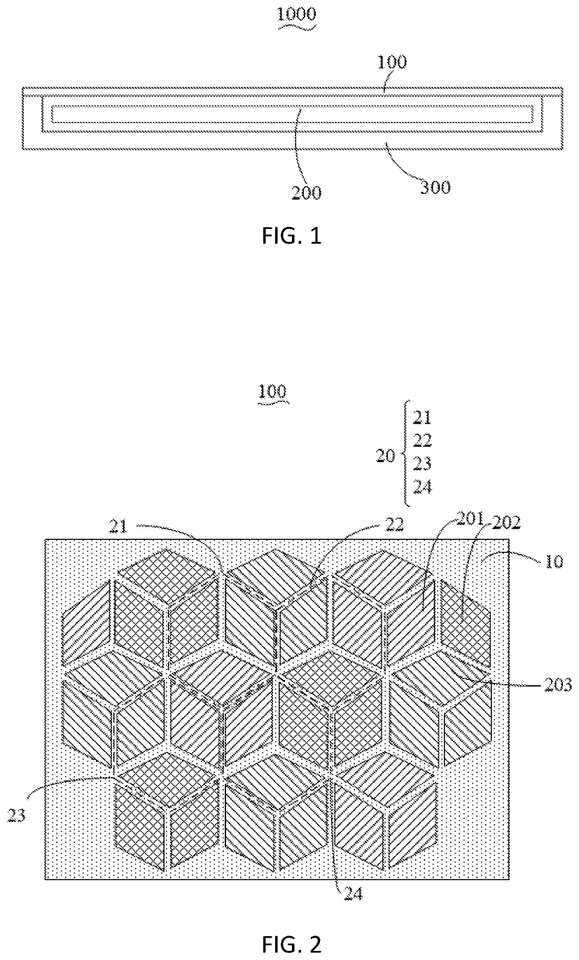

Referring to FIG. 1, FIG. 1 is a structural schematic diagram of a display apparatus 1000 according to an embodiment of the present application. The display apparatus 1000 can include a light emitting substrate 100, a control circuit 200, and a housing 300. It should be noted that contents of the display apparatus 1000 in FIG. 1 are not limited thereto, and can further include other devices such as a camera, an antenna structure, a fingerprint unlock module, etc.

Wherein, the light emitting substrate 100 is disposed on the housing 300.

In some embodiments, the light emitting substrate 100 can be secured to the housing 300 to form a sealed space between the light emitting substrate 100 and the housing 300 that accommodates the control circuit 200 and other devices.

In some embodiments, the housing 300 can be made of flexible materials such as a plastic housing, a silicone rubber housing, etc.

Wherein, the control circuit 200 is installed in the housing 300, the control circuit 200 can be a mainboard of the display apparatus 1000, and one, two, or more functional components of a battery, an antenna structure, a microphone, a speaker, a headphone interface, a universal serial bus interface, a camera, a distance sensor, an ambient light sensor, a receiver, a processor, etc. can be integrated in the control circuit 200.

Wherein, the light emitting substrate 100 is installed in the housing 300; meanwhile, the light emitting substrate 100 is electrically connected to the control circuit 200 to form a display surface of the display apparatus 1000. The light emitting substrate 100 can include a display area and a non-display area. The display area can be configured to display pictures of the display apparatus 1000, provide touch control for users, etc. The non-display area can be used to configure various functional components.

Referring to FIG. 2, FIG. 2 is a first structural schematic diagram of the light emitting substrate 100 according to an embodiment of the present application. The light emitting substrate 100 includes a base 10, and a plurality of pixel unit sets 20 arranged in rows on the base 10, wherein each pixel unit set 20 of the plurality of pixel unit sets 20 includes a first sub-pixel 201, a second sub-pixel 202, and a third sub-pixel 203 having colors different from each other, adjacent sub-pixels of the first sub-pixel 201, the second sub-pixel 202, and the third sub-pixel 203 have space therebetween, the plurality of pixel unit sets 20 arranged in a same row includes a first pixel unit set 21 and a second pixel unit set 22 adjacent to each other, the second sub-pixel 202 of the first pixel unit set 21 and the first sub-pixel 201 of the second pixel unit set 22 have a same color, the second sub-pixel 202 of a third pixel unit set 23 in an adjacent row and the third sub-pixel 203 of the first pixel unit set 21 have a same color, the first sub-pixel 201 of a fourth pixel unit set 24 and the third sub-pixel 203 of the first pixel unit set 21 have a same color, the third pixel unit set 23 and the fourth pixel unit set 24 are arranged in a same row, and the third pixel unit set 23 and the fourth pixel unit set 24 are located on two sides of the first pixel unit set 21.

In particular, as can be seen from FIG. 2, the plurality of pixel unit sets 20 on the base 10 is arranged in rows, and each pixel unit set 20 includes the first sub-pixel 201, the second sub-pixel 202, and the third sub-pixel 203. Pixel colors of first sub-pixel 201, the second sub-pixel 202, and the third sub-pixel 203 are selected from red, green, and blue (R, G, and B), and colors of sub-pixels of each of the pixel unit sets 20 are different from each other to make each of the pixel unit sets 20 formed include red, green, and blue colors and increase resolution.

Wherein, the second sub-pixel 202 of the first pixel unit set 21 and the first sub-pixel 201 of the second pixel unit set 22 in a same row have a same color, the second sub-pixel 202 of the third pixel unit set 23 located in a row adjacent to the first pixel unit set 21 and the third sub-pixel 203 of the first pixel unit set 21 have a same color, the first sub-pixel 201 of the fourth pixel unit set 24 located in a same row as that of the third pixel unit set 23 and adjacent to the third pixel unit set 23 and the third sub-pixel 203 of the first pixel unit set 21 have a same color, and the third pixel unit set 23 and the fourth pixel unit set 24 are respectively located on two sides of the first pixel unit set 21.

It can be understood that the first sub-pixel 201, the second sub-pixel 202, and the third sub-pixel 203 have space therebetween, and arrangement of the space can prevent excessively close arrangement of the first sub-pixel 201, the second sub-pixel 202, and the third sub-pixel 203 that leads to color mixture when emitting light.

In some embodiments, the pixel unit sets 20 in adjacent rows are shifted with a preset width, and the preset width is equal to half of a width of the pixel unit sets 20 in a horizontal direction. In particular, it can be seen that the third pixel unit set 23 and the fourth pixel unit set 24 are located in an adjacent row of the first pixel unit set 21 and the second pixel unit set 22, and the third pixel unit set 23 and the fourth pixel unit set 24 are shifted half of the width of the pixel unit sets 20 with respect to the first pixel unit set 21 in a horizontal direction to closely arrange the pixel unit sets 20 in different rows.

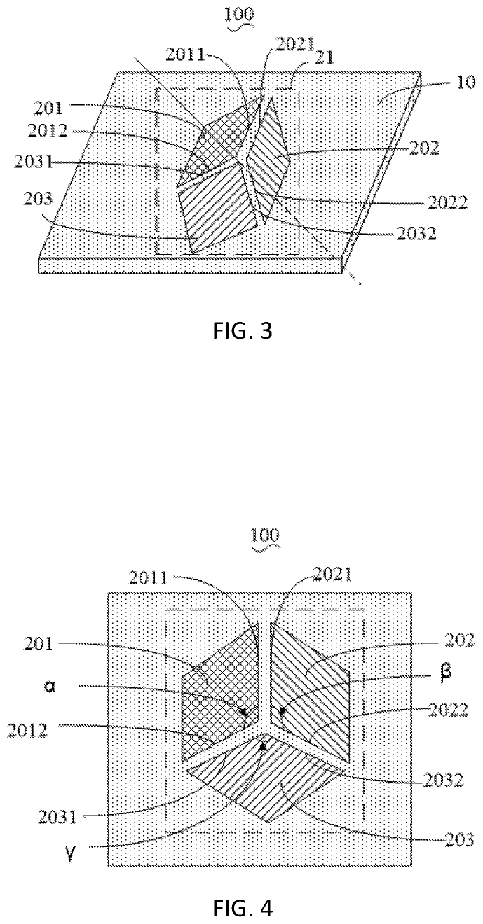

In some embodiments, as shown in FIG. 3, FIG. 3 is a second structural schematic diagram of the light emitting substrate 100 according to an embodiment of the present application. The first pixel unit set 21 is illustrated here, wherein the first sub-pixel 201, the second sub-pixel 202, and the third sub-pixel 203 are arranged surrounding a central axis, and the central axis is perpendicular to the base.

In some embodiments, the first sub-pixel 201, the second sub-pixel 202, and the third sub-pixel 203 of the pixel unit sets have a same shape.

Wherein, each shape of the first sub-pixel 201, the second sub-pixel 202, and the third sub-pixel 203 is a rhombus, a rectangle, a triangle, etc., which is not limited thereto.

In some embodiments, as shown in FIG. 3 and FIG. 4, FIG. 4 is a third structural schematic diagram of the light emitting substrate 100 according to an embodiment of the present application, and FIG. 4 is a top view of FIG. 3. The first sub-pixel 201 includes a first side 2011 and a second side 2012 adjacent to the first side 2011, and the first side 2011 and the second side 2012 are sides closer to the central axis. The second sub-pixel 202 includes a third side 2021 and a fourth side 2022 adjacent to the third side 2021, and the third side 2021 and the fourth side 2022 are sides closer to the central axis. The third sub-pixel 203 includes a fifth side 2031 and a sixth side 2032 adjacent to the fifth side 2031, and the fifth side 2031 and the sixth side 2032 are sides closer to the central axis.

In some embodiments, a sum of a first angle α, a second angle β, and a third angle γ is 360 degrees, the first angle α is an angle formed by the first side 2011 and the second side 2012, the second angle β is an angle formed by the third side 2021 and the fourth side 2022, and the third angle γ is an angle formed by the fifth side 2031 and the sixth side 2032.

Wherein, the third side 2021 is disposed facing the first side 2011, the fifth side 2031 is disposed facing the second side 2012, and the fourth side 2022 is disposed facing the sixth side 2032.

It can be understood that in order to closely arrange sub-pixels on the base 10, the third side 2021 of the second sub-pixel 202 can be disposed facing the first side 2011 of the first sub-pixel 201, the fifth side 2031 of the third sub-pixel 203 can be disposed facing the second side 2012 of the first sub-pixel 201, and the fourth side 2022 of the second sub-pixel 202 can be disposed facing the sixth side 2032 of the third sub-pixel 203, such that a shape of the pixel unit set 20 formed by the first sub-pixel 201, the second sub-pixel 202, and the third sub-pixel 203 is a regular hexagon, and a center point of the regular hexagon is located at the central axis.

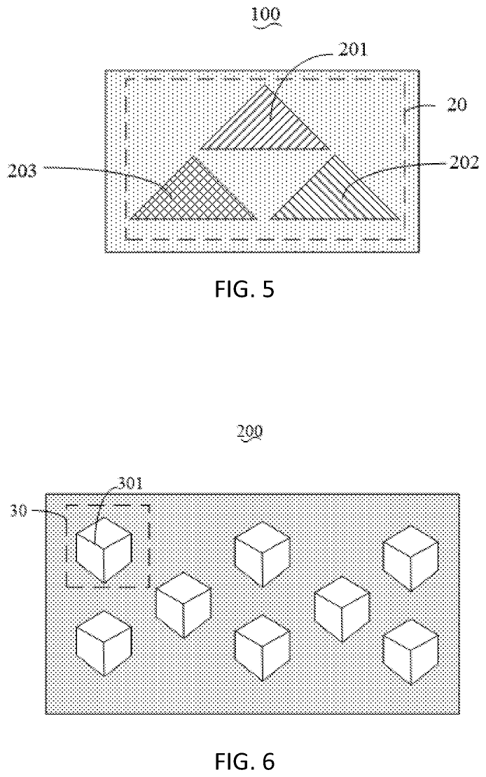

In some embodiments, as shown in FIG. 5, FIG. 5 is a fourth structural schematic diagram of the light emitting substrate 100 according to an embodiment of the present application. Wherein, each shape of the first sub-pixel 201, the second sub-pixel 202, and the third sub-pixel 203 is a regular triangle, and a shape of the pixel unit set 20 formed by the first sub-pixel 201, the second sub-pixel 202, and the third sub-pixel 203 is a regular triangle.

Obviously, each shape of the first sub-pixel 201, the second sub-pixel 202, and the third sub-pixel 203 is not limited to a rhombus and a triangle, and can also be a rectangle, etc., and details are omitted here.

It can be seen that when manufacturing pixel unit sets 20 as shown in FIG. 2, regular hexagons consisting of a plurality of first sub-pixels 201, a plurality of second sub-pixels 202, or a plurality of third sub-pixels 203 are formed on the base 10 by using FMMs. Hence, as shown in FIG. 6, FIG. 6 is a structural schematic diagram of masks 200 for manufacturing sub-pixels according to an embodiment of the present application.

It can be seen, in FIG. 2, that sub-pixels having a same color form a regular hexagon, and the regular hexagon includes three same sub-pixels. Hence, corresponding masks 200 also have a regular hexagon opening 30, a blocker 301 is disposed on the regular hexagon opening 30, and the blocker 301 is Y-shaped.

In this way, during processing, the first sub-pixel 201, the second sub-pixel 202, and the third sub-pixel 203 can be masked by using a same mask, there is no need to change different masks for different sub-pixels, and production capacity is increased and damage when cleaning masks is reduced. Because distance between adjacent openings of masks 200 according to the present application is larger, deformation of masks 200 during processing can be prevented.

An embodiment of the present application provides a light emitting substrate that includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the second sub-pixel of the first pixel unit set and the first sub-pixel of the second pixel unit set of the plurality of pixel unit sets arranged in a same row that are adjacent to each other have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set. Arranging space between adjacent sub-pixels can prevent color mixture, sub-pixels of each pixel unit set with colors different from each other can increase resolution, and by using a mask to yield space between each sub-pixel arranged on the base, it is not necessary to reduce size of openings of the mask, while distance between adjacent openings on the mask is increased and manufacturing difficulty is reduced.

An embodiment of the present application further provides a light emitting substrate that includes a base, and a plurality of pixel unit sets arranged in rows on the base, wherein each pixel unit set of the plurality of pixel unit sets includes a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row includes a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set. The first sub-pixel, the second sub-pixel, and the third sub-pixel are arranged surrounding a central axis, and the central axis is perpendicular to the base. The pixel unit sets in adjacent rows are shifted with a preset width, and the preset width is equal to half of a width of the pixel unit sets in a horizontal direction.

Wherein, the first sub-pixel, the second sub-pixel, and the third sub-pixel of the pixel unit set have a same shape, each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

Although the present application has been explained in relation to its preferred embodiment, it does not intend to limit the present application. It will be apparent to those skilled in the art having regard to this present application that other modifications of the exemplary embodiments beyond these embodiments specifically described here may be made without departing from the spirit of the application. Accordingly, such modifications are considered within the scope of the application as limited solely by the appended claims.

What is claimed is:

1. A light emitting substrate, comprising a base, and a plurality of pixel unit sets arranged in rows on the base, wherein each pixel unit set of the plurality of pixel unit sets comprises:
a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row comprises a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set.

2. The light emitting substrate as claimed in claim 1, wherein the first sub-pixel, the second sub-pixel, and the third sub-pixel are arranged surrounding a central axis, and the central axis is perpendicular to the base.

3. The light emitting substrate as claimed in claim 2, wherein the first sub-pixel, the second sub-pixel, and the third sub-pixel of the pixel unit sets have a same shape.

4. The light emitting substrate as claimed in claim 3, wherein the first sub-pixel comprises a first side and a second side adjacent to the first side, the first side and the second side are sides closer to the central axis, the second sub-pixel comprises a third side and a fourth side adjacent to the third side, the third side and the fourth side are sides closer to the central axis, the third sub-pixel comprises a fifth side and a sixth side adjacent to the fifth side, and the fifth side and the sixth side are sides closer to the central axis.

5. The light emitting substrate as claimed in claim 4, wherein a sum of a first angle, a second angle, and a third angle is 360 degrees, the first angle is an angle formed by the first side and the second side, the second angle is an angle formed by the third side and the fourth side, and the third angle is an angle formed by the fifth side and the sixth side.

6. The light emitting substrate as claimed in claim 5, wherein the third side is disposed facing the first side, the fifth side is disposed facing the second side, and the fourth side is disposed facing the sixth side.

7. The light emitting substrate as claimed in claim 6, wherein each shape of the first sub-pixel, the second sub-pixel, and the third sub-pixel is a rhombus, a shape of the pixel unit set formed by the first sub-pixel, the second sub-pixel, and the third sub-pixel is a regular hexagon, and a center point of the regular hexagon is located at the central axis.

8. The light emitting substrate as claimed in claim 1, wherein the pixel unit sets in adjacent rows are shifted with a preset width, and the preset width is equal to half of a width of the pixel unit sets in a horizontal direction.

9. The light emitting substrate as claimed in claim 2, wherein each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

10. A display apparatus, comprising a light emitting substrate and a housing, wherein the light emitting substrate is disposed on the housing, and the light emitting substrate comprises:
a base, and a plurality of pixel unit sets arranged in rows on the base, wherein each pixel unit set of the plurality of pixel unit sets comprises:
a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row comprises a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, and the third pixel unit set and the fourth pixel unit set are located on two sides of the first pixel unit set.

11. The display apparatus as claimed in claim 10, wherein the first sub-pixel, the second sub-pixel, and the third sub-pixel are arranged surrounding a central axis, and the central axis is perpendicular to the base.

12. The display apparatus as claimed in claim 11, wherein the first sub-pixel, the second sub-pixel, and the third sub-pixel of the pixel unit sets have a same shape.

13. The display apparatus as claimed in claim 12, wherein the first sub-pixel comprises a first side and a second side adjacent to the first side, the first side and the second side are sides closer to the central axis, the second sub-pixel comprises a third side and a fourth side adjacent to the third side, the third side and the fourth side are sides closer to the central axis, the third sub-pixel comprises a fifth side and a sixth side adjacent to the fifth side, and the fifth side and the sixth side are sides closer to the central axis.

14. The display apparatus as claimed in claim 13, wherein a sum of a first angle, a second angle, and a third angle is 360 degrees, the first angle is an angle formed by the first side and the second side, the second angle is an angle formed by the third side and the fourth side, and the third angle is an angle formed by the fifth side and the sixth side.

15. The display apparatus as claimed in claim 14, wherein the third side is disposed facing the first side, the fifth side is disposed facing the second side, and the fourth side is disposed facing the sixth side.

16. The display apparatus as claimed in claim 15, wherein each shape of the first sub-pixel, the second sub-pixel, and the third sub-pixel is a rhombus, a shape of the pixel unit set formed by the first sub-pixel, the second sub-pixel, and the third sub-pixel is a regular hexagon, and a center point of the regular hexagon is located at the central axis.

17. The display apparatus as claimed in claim 10, wherein the pixel unit sets in adjacent rows are shifted with a preset width, and the preset width is equal to half of a width of the pixel unit sets in a horizontal direction.

18. The display apparatus as claimed in claim 11, wherein each shape of the first sub-pixel, the second sub-pixel, and the third sub-pixel is a regular triangle, and a shape of the pixel unit set formed by the first sub-pixel, the second sub-pixel, and the third sub-pixel is a regular triangle.

19. A light emitting substrate, comprising a base, and a plurality of pixel unit sets arranged in rows on the base, wherein each pixel unit set of the plurality of pixel unit sets comprises:
a first sub-pixel, a second sub-pixel, and a third sub-pixel having colors different from each other, wherein adjacent sub-pixels of the first sub-pixel, the second sub-pixel, and the third sub-pixel have space therebetween, the plurality of pixel unit sets arranged in a same row comprises a first pixel unit set and a second pixel unit set adjacent to each other, the second sub-pixel of the first pixel unit set and the first sub-pixel of the second pixel unit set have a same color, the second sub-pixel of a third pixel unit set in an adjacent row and the third sub-pixel of the first pixel unit set have a same color, the first sub-pixel of a fourth pixel unit set and the third sub-pixel of the first pixel unit set have a same color, the third pixel unit set and the fourth pixel unit set are arranged in a same row, the third pixel unit set and the fourth pixel unit set are located on two sides of the first pixel unit set, the first sub-pixel, the second sub-pixel, and the third sub-pixel are arranged surrounding a central axis, the central axis is perpendicular to the base, the pixel unit sets in adjacent rows are shifted with a preset width, and the preset width is equal to half of a width of the pixel unit sets in a horizontal direction.

20. The light emitting substrate as claimed in claim 19, wherein the first sub-pixel, the second sub-pixel, and the third sub-pixel of the pixel unit sets have a same shape, each shape of the first sub-pixel, the second sub-pixel, and the third sub-pixel is a regular triangle, and a shape of the pixel unit set formed by the first sub-pixel, the second sub-pixel, and the third sub-pixel is a regular triangle.
